(19) United States
(12) Patent Application Publication
(10) Pub. No.: US 2026/0156835 A1
(43) Pub. Date: Jun. 4, 2026

(54) CMO-BASED METALLIC FILAMENT RESISTIVE RANDOM ACCESS MEMORY

(71) Applicant: International Business Machines Corporation, Armonk, NY (US)

(72) Inventors: Donato Francesco Falcone, Langnau am Albis (CH); Valeria Bragaglia, Thalwil (CH); Tommaso Stecconi, Zurich (CH); Ghazi Sarwat Syed, Kilchberg (CH); Vara Sudananda Prasad Jonnalagadda, RUESCHLIKON (CH); Abu Sebastian, Adliswil (CH); Bert Jan Offrein, Schoenenberg (CH)

(21) Appl. No.: 18/964,150

(22) Filed: Nov. 29, 2024

(51) Int. Cl. H10B 63/00

(52) U.S. Cl. CPC H10B 63/30; H10B 63/80

(57) ABSTRACT

A CMO-based metallic filament (MF) resistive random access memory (MF-ReRAM) cell is provided in which the metallic filament is specifically designed to confine electric potential of the top electrode in a circular plug area of the MF. The CMO-based MF-ReRAM cell has non-volatile-multilevel storage capability in the back-end-of-the-line (BEOL), and such a memory cell can be integrated in a highly dense crossbar architecture.

### BACKGROUND

The present application relates to non-volatile memory (NVM), and more particularly to a two-terminals forming-free conductive metal oxide (CMO)-based metallic filament (MF) resistive random access memory (ReRAM) cell with non-volatile-multilevel storage capability in the back-end-of-the-line (BEOL), as well the integration of such a memory cell in a highly dense crossbar architecture.

Non-volatile memory (NVM) or non-volatile storage is a type of computer memory that can retain stored information even after the power is removed. In contrast, volatile memory needs constant power in order to retain data. NVMs, such as, for example, ReRAM (or sometime merely RRAM), phase change random access memory (PCRAM), and conductive bridge random access memory (CBRAM), are getting renewed attentions for potential applications to neuromorphic computing with in-memory processing capability which reduces power consumption significantly and eliminates data busing time between memory and the central processing unit (CPU) of conventional complementary metal oxide semiconductor (CMOS) based neuromorphic computing. ReRAM is considered as a promising technology for electronic synapse devices or memristors for neuromorphic computing as well as high-density and high-speed NVM applications.

### SUMMARY

A CMO-based metallic filament (MF) resistive random access memory (e.g., MF-ReRAM) cell is provided in which the metallic filament is specifically designed to confine electric potential of the top electrode in a circular plug area of the MF. The CMO-based MF-ReRAM cell has non-volatile-multilevel storage capability in BEOL, and such a memory cell can be integrated in a highly dense crossbar architecture.

In one aspect of the present application, a NVM cell is provided. In one embodiment of the present application, the NVM cell includes a CMO structure located on a portion of a bottom electrode, and a top electrode located above the CMO structure, in which the top electrode is connected to the CMO structure by a cylindrical metallic filament. The cylindrical metallic filament substantially confines electric potential of the top electrode in a circular plug area of π(r_{MF})², where r_{MF} is a radius of the cylindrical metallic filament, as measured from a bottommost portion of the cylindrical metallic filament.

In another aspect of the present application, a highly dense crossbar memory architecture is provided. In one embodiment of the present application, the highly dense crossbar memory architecture includes a plurality 1T-1MFReRAM cells arranged in rows and columns, each 1T-1MFReRAM cell including a transistor, T, and a NVM cell (e.g., MF-ReRAM cell). The NVM cell includes a CMO structure located on a portion of a bottom electrode, and a top electrode located above the CMO structure, in which the top electrode is connected to the CMO structure by a cylindrical metallic filament, and the cylindrical metallic filament substantially confines electric potential of the top electrode in a circular plug area of π(r_{MF})², where r_{MF} is a radius of the cylindrical metallic filament, as measured from a bottommost portion of the cylindrical metallic filament. The highly dense crossbar memory architecture further includes at least one horizontal line of bit lines, each bit line in the at least one horizontal line of bit lines is connected to the top electrode of each NVM cell in a corresponding row of 1T-1MFReRAM cells, at least one horizontal line of word lines, each word line in the at least one horizontal line of word lines is connected to a gate electrode of each of the transistors in a corresponding row of 1T-1MFReRAM cells, and at least one vertical line of source lines, each source line is connected to a source region of each of the transistors in a corresponding column of 1T-1MFReRAM cells.

In another embodiment of the present application, the highly dense crossbar memory architecture includes a plurality MF-ReRAM cells arranged in rows and columns. Each MF-ReRAM includes a CMO structure located on a portion of a bottom electrode, and a top electrode located above the CMO structure, in which the top electrode is connected to the CMO structure by a cylindrical metallic filament, and the cylindrical metallic filament substantially confines electric potential of the top electrode in a circular plug area of π(r_{MF})², where r_{MF} is a radius of the cylindrical metallic filament, as measured from a bottommost portion of the cylindrical metallic filament. The highly dense crossbar memory architecture further includes at least one horizontal line of bit lines, each bit line in the at least one horizontal line of bit lines is connected to the top electrode of each MF-ReRAM cell, and at least one vertical line of source lines, each source line is connected to the bottom electrode of each MF-ReRAM cell.

### BRIEF DESCRIPTION OF THE DRAWINGS

FIG. 1A is a cross sectional view of an exemplary 2-terminals forming-free CMO-based MF-ReRAM cell in accordance with an embodiment of the present application.

FIG. 1B is a cross sectional view of an exemplary 2-terminals forming-free CMO-based MF-ReRAM cell in accordance with another embodiment of the present application.

FIGS. 2A-2C are cross sectional views illustrating multi-level programming of an exemplary 2-terminals forming-free CMO-based MF-ReRAM cell in accordance with an embodiment of the present application in which FIG. 2A is of the as-formed resistive state, and FIGS. 2B-2C are resistive states after applying identical negative pulses to the top electrode.

FIG. 3A is a cross sectional view illustrating negative write and read operations for an exemplary 2-terminals forming-free CMO-based MF-ReRAM cell in accordance with an embodiment of the present application.

FIG. 3B is a graph of the negative write and read operations for the exemplary 2-terminals forming-free CMO-based MF-ReRAM cell illustrated in FIG. 3A.

FIG. 4A-4C are cross sectional views illustrating multi-level programming of an exemplary 2-terminals forming-free CMO-based MF-ReRAM cell in accordance with an embodiment of the present application in which FIG. 3A is of the as-formed resistive state, and FIGS. 4B-4C are resistive states after applying identical positive pulses to the top electrode.

FIG. 5A is a cross sectional view illustrating positive write and read operations for an exemplary 2-terminals forming-free CMO-based MF-ReRAM cell in accordance with an embodiment of the present application.

FIG. 5B is a graph of the negative write and read operations for the exemplary 2-terminals forming-free CMO-based MF-ReRAM cell illustrated in FIG. 5A.

FIGS. 6A-6C are cross sectional views of various exemplary 2-terminals forming-free CMO-based MF-ReRAM cells in accordance with an embodiment of the present application showing controllable resistive switching levels that can be achieved.

FIG. 7A is a cross sectional view of a 1T-1MFReRAM cell in accordance with an embodiment of the present application.

FIG. 7B is a circuit diagram of the 1T-1MFReRAM cell illustrated in FIG. 7A.

FIG. 7C illustrates a high density crossbar memory architecture including a plurality 1T-1MFReRAM cells.

FIG. 8 illustrates a high density crossbar memory architecture including a plurality MF-ReRAM cells.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Advancing the functionalities of modern CMOS technology mainly consists in (i) shrinking the process node to increase the number of transistors and their computational power and energy efficiency; (ii) adding local memory by integrating more memory closely with processing units to improve the latency, bandwidth, efficient and cost, and (iii) compute-in-memory which performs some of the arithmetic and logic operation at a location where the data is stored.

Modern artificial intelligence (AI) workloads require massive data transfer between processing units (e.g., CPUs/GPUs) and storage memory resulting in time and energy efficiency when run on conventional Von-Neuman based architectures.

Analog in memory computing architecture based on a crossbar array of ReRAM cells represents a promising approach to unlock energy-efficient in memory training and inference operations in analog domain, in 0(1) time complexity.

In this regard, conventional 2-terminals multilevel CMO-based filamentary ReRAM cells may represent a technological breakthrough due to (i) gradual resistive switching in both directions (synaptic potentiation and depressions) using a stream of identical pulse, showing more than 5 bits per cell, and (ii) highly scaled area with CMOS-compatible materials. However, the required soft-dielectric breakdown in such cells represents one of the major challenges in terms of cell area scaling compatibility with the latest advanced CMOS nodes and stochasticity.

The present application provides a highly scalable and CMOS-compatible 2 terminals forming-free CMO-based MF-ReRAM cell with non-volatile-multilevel capability which can functionalize a BEOL structure. Such analog MF-ReRAM cells can be integrated with advanced CMOS nodes in crossbar arrays (in 1 MF-ReRAM cell or 1 transistor (T)-1MFReRAM cell) to implement efficient AI workloads with an ultra-scaled cell area.

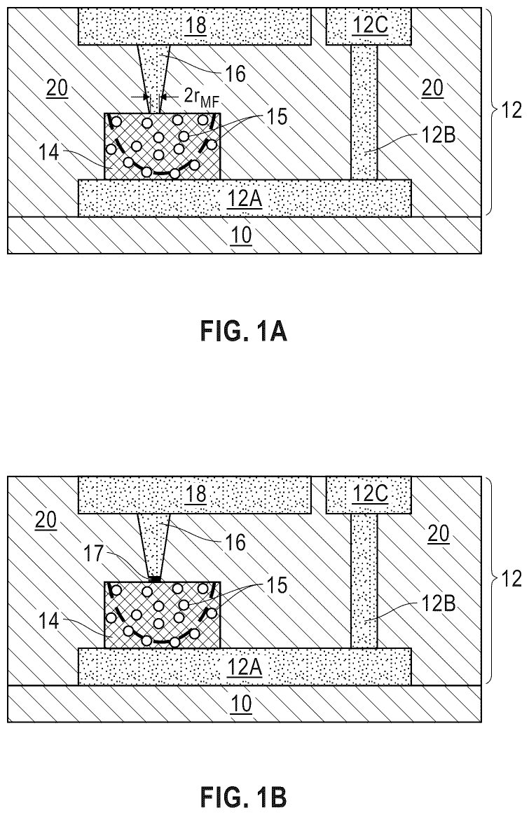

In one aspect of the present application, a NVM cell (i.e., MF-ReRAM cell) such as illustrated in FIGS. 1A-1B is provided. In one embodiment of the present application, the NVM cell includes CMO structure 14 located on a portion of a bottom electrode 12, and top electrode 18 located above the CMO structure 14, in which the top electrode 18 is connected to the CMO structure 14 by cylindrical metallic filament 16. The cylindrical metallic filament 16 substantially confines electric potential of the top electrode 18 in a circular plug area of π(r_{MF})², where r_{MF} is a radius of the cylindrical metallic filament 16, as measured from a bottommost portion of the cylindrical metallic filament 16. The NVM cell of the present application is an analog forming-free MFReRAM in which graduation migration of oxygen vacancy defects 15 are triggered once a required migration energy is provided by both electric field and temperature confinement causes resistive switching. In the present application, the defect migration energy is typically greater than or equal to 1 eV. Such an NVM cell can have multi-level resistance states which can be obtained by applying energy pulses (e.g., negative or positive) to the top electrode 18.

In some embodiments and as illustrated in FIG. 1A, the cylindrical metallic filament 16 is in direct physical contact with the CMO structure 14.

In other embodiments and as illustrated in FIG. 1B, diffusion barrier layer 17 is present separating the cylindrical metallic filament 16 from the CMO structure 14. This aspect of the present application decrease migration of the oxygen vacancy defects 15 into the cylindrical metallic filament 16 and thus provides greater confinement of the oxygen vacancy defects 15 in the CMO structure 14.

In embodiments of the present application and as illustrated in FIGS. 1A-1B, dielectric region 20 is present that embeds each of the bottom electrode 12, the CMO structure 14, the cylindrical metallic filament 16 and the top electrode 18, the dielectric region 20 is a component of an BEOL structure. This aspect of the present application enables integration of the NVM cell into a BEOL structure.

In embodiments of the present application, CMO structure 14 has a lower electrical conductivity, σ, and thermal conductivity, k, as compared to the cylindrical metallic filament 16. This aspect of the present application enables the CMO structure 14 to act as an electric field and thermal confinement layer due to the spreading and thermal resistances. A further explanation of this can be found, for example, in an article to Falcone et al. entitled “Analytic Modelling of the Transport in Analog Filamentary Conductive-Metal-Oxide/HfOₓ ReRAM Devices”, Nanoscale Horizons, Issue 5, 2024.

In embodiments of the present application the CMO structure 14 is composed of a metal having a concentration of oxygen vacancy defects present therein and a modulation (i.e., change in location) of the oxygen vacancy defects 15 in the CMO structure 14 provides analog resistive switching.

In such analog resistive switching embodiments, the concentration of the oxygen vacancy defects 15 is randomly distributed throughout the CMO structure 14 and the NVM cell is at a low-resistive state.

In such analog resistive switching embodiments, the concentration of the oxygen vacancy defects 15 is greater at a topmost surface of the CMO structure 14 than a bulk portion of the CMO structure 14 and the NVM cell is a high resistive state.

In some embodiments, a resistive state of CMO structure 14 is controlled by the r_{MF}, a concentration of the oxygen vacancy defects in the CMO structure or a combination of r_{MF} and the concentration of the oxygen vacancy defects present in the CMO structure.

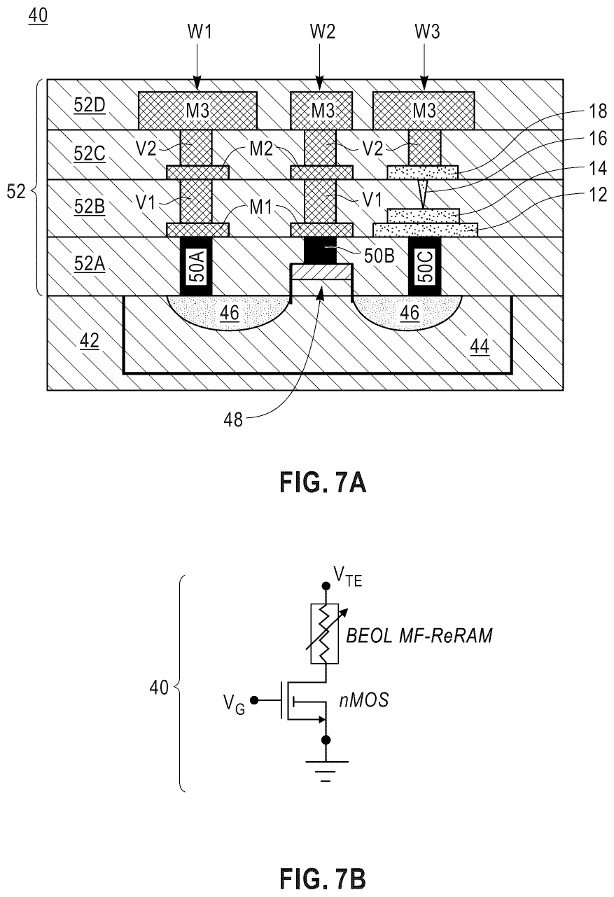

In another aspect of the present application, a highly dense crossbar memory architecture such as illustrated in FIG. 7C is provided. In one embodiment of the present application, the highly dense crossbar memory architecture includes a plurality 1T-1MFReRAM cells 40 (one of which is illustrated in FIGS. 7A-7B) arranged in rows and columns, each 1T-1MFReRAM cell including a transistor and a NVM cell. The NVM cell includes CMO structure 14 located on a portion of bottom electrode 12, and top electrode 18 located above the CMO structure 14, in which the top electrode 18 is connected to the CMO structure 14 by a cylindrical metallic filament 16, and the cylindrical metallic filament 16 substantially confines electric potential of the top electrode 18 in a circular plug area of π(r_{MF}), where r_{MF} is a radius of the cylindrical metallic filament 16, as measured from a bottommost portion of the cylindrical metallic filament 16. The highly dense crossbar memory architecture further includes at least one horizontal line of bit lines (BL), each bit line (BL) in the at least one horizontal line of bit lines is connected to the top electrode 18 of each NVM cell in a corresponding row of 1T-1MFReRAM cells, at least one horizontal line of word lines (WL), each word line (WL) in the at least one horizontal line of word lines is connected to a gate electrode of each of the transistors in a corresponding row of 1T-1MFReRAM cells, and at least one vertical line of source lines (SL), each source line (SL) is connected to a source region (one of the source/drain regions 46 shown in FIG. 7A) of each of the transistors in a corresponding column of 1T-1MFReRAM cells.

In some embodiments of the crossbar memory architecture illustrated in FIG. 7C, the cylindrical metallic filament 16 of each NVM cell is in direct physical contact with the CMO structure 14.

In some embodiments of the crossbar memory architecture illustrated in FIG. 7C, diffusion barrier layer 17 is present separating the cylindrical metallic filament 16 from the CMO structure 14. This aspect of the present application decrease migration of the oxygen vacancy defects 15 into the cylindrical metallic filament 16.

In embodiments of the crossbar memory architecture illustrated in FIG. 7C, the CMO structure 14 has a lower electrical conductivity, σ, and thermal conductivity, k, as compared to the cylindrical metallic filament 16. This aspect of the present application enables the CMO structure 14 to act as an electric field and thermal confinement layer due to the spreading and thermal resistances.

In embodiments of the crossbar memory architecture illustrated in FIG. 7C, the CMO structure 14 is composed of a metal having a concentration of oxygen vacancy defects 15 present therein and a modulation of the oxygen vacancy defects in the CMO structure 14 provides analog resistive switching.

In some embodiments of the crossbar memory architecture illustrated in FIG. 7C, a resistive state of the CMO structure 14 is controlled by the r_{MF}, a concentration of the oxygen vacancy defects 15 in the CMO structure 14 or a combination of r_{MF} and the concentration of the oxygen vacancy defects 15 present in the CMO structure 14.

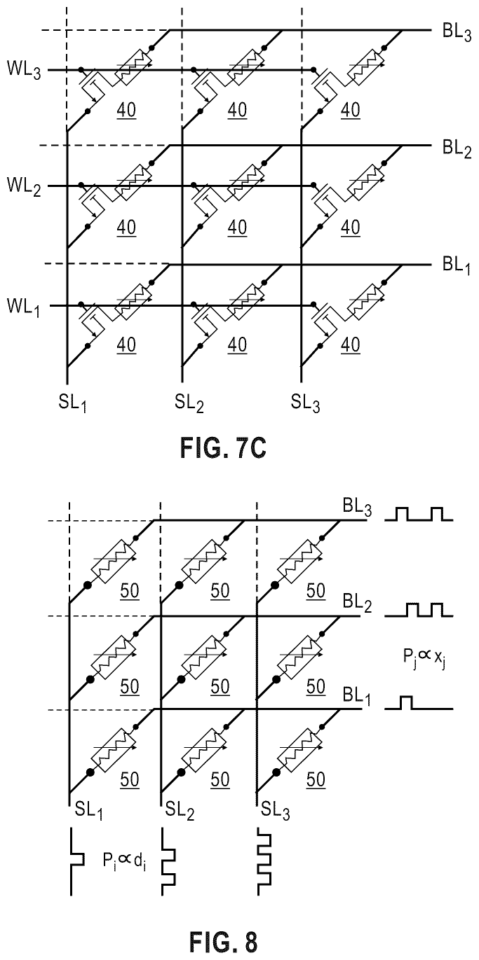

In another embodiment of the present application illustrated in FIG. 8, the highly dense crossbar memory architecture includes a plurality1MF-ReRAM cells arranged in rows and columns (see, for example, FIG. 8). Each MF-ReRAM cell includes CMO structure 14 located on a portion of bottom electrode 12, and top electrode 18 located above the CMO structure 14, in which the top electrode 18 is connected to the CMO structure 14 by cylindrical metallic filament 16, the cylindrical metallic filament 16 substantially confines electric potential of the top electrode 18 in a circular plug area of π(r_{MF})², where r_{MF} is a radius of the cylindrical metallic filament 16, as measured from a bottommost portion of the cylindrical metallic filament 16. The highly dense crossbar memory architecture further includes at least one horizontal line of bit lines (BL), each bit line (BL) in the at least one horizontal line of bit lines is connected to the top electrode 18 of each MF-ReRAM cell, and at least one vertical line of source lines (SL), each source line (SL) is connected to the bottom electrode of each MF-ReRAM cell.

In some embodiments of the crossbar memory architecture illustrated in FIG. 8, the CMO structure 14 has a lower electrical conductivity, σ, and thermal conductivity, k, as compared to the cylindrical metallic filament 16.

In some embodiments of the crossbar memory architecture illustrated in FIG. 8, the CMO structure 14 is composed of a metal having a concentration of oxygen vacancy defects 15 present therein, wherein a modulation of the oxygen vacancy defects in the CMO structure 14 provides analog resistive switching.

In some embodiments of the crossbar memory architecture illustrated in FIG. 8, a resistive state of the CMO structure 14 is controlled by the r_{MF}, a concentration of the oxygen vacancy defects 15 in the CMO structure 14 or a combination of r_{MF} and the concentration of the oxygen vacancy defects present in the CMO structure 14.

These and other aspect of the present application will now be described in greater detail. Notably, FIGS. 1A-1B illustrate a non-volatile memory (NVM) cell (i.e., 2-terminals forming-free CMO-based MF-ReRAM cell) in accordance with different embodiments of the present application. Each NVM cell includes bottom electrode 12, CMO structure 14 located on a portion of the bottom electrode 12, top electrode 18 located above the CMO structure 14, and a cylindrical metallic filament 16 connecting the CMO structure 14 to the top electrode 18. In accordance with the present application and as previously mentioned above, the cylindrical metallic filament 16 is designed to substantially confine the electric potential of the top electrode 18 in a circular plug area of π(r_{MF})², where r_{MF} is a radius of the cylindrical metallic filament 16, as measured from a bottommost portion of the cylindrical metallic filament 16 that is in contact with, or close proximity to, the CMO structure 14. In embodiments of the present application, r_{MF} can be from 5 nm to 50 nm, with a r_{MF} from 5 nm to 10 nm being more typical. By reducing the radius of cylindrical metallic filament 16, an enhanced confinement of the electric potential from top electrode 18 is achieved within the CMO structure 14, resulting in a resistive switching event occurring at lower operating voltages.

In some embodiments, and as illustrated in FIG. 1A, the bottommost portion of the cylindrical metallic filament 16 is in direct physical contact with the CMO structure 14 (in such an embodiment an interface is formed between the CMO structure 14 and the cylindrical metallic filament 16). In other embodiments, and as is shown in FIG. 1B, a diffusion barrier layer 17 can be positioned between the bottommost portion of the cylindrical metallic filament 16 and the CMO structure 14. When present, the diffusion barrier layer 17 can be composed of a dielectric oxide such as, for example, Al₂O₃ or HfOₓ. When present, the diffusion barrier layer 17 can serve as a defect barrier diffusion layer substantially preventing defects (i.e., oxygen vacancy defects 15) within the CMO structure 14 from traversing into and through the cylindrical metallic filament 16. When present, the diffusion barrier layer 17 is a sub-nm layer whose thickness is, for example, from 0.05 nm to less than 1 nm.

In some embodiments of the present application, and as is illustrated in FIGS. 1A-1B, the bottom electrode 12 includes a first horizontal portion 12A and a second horizontal portion 12C that are interconnected by a vertical portion 12B. In such an embodiment, the second horizontal portion 12C of the bottom electrode 12 can have a topmost surface that is substantially coplanar with a topmost surface of the top electrode 18. In other embodiments including the second horizontal portion 12C of the bottom electrode 12, a topmost surface of the second horizontal portion 12C can be vertically offset from (i.e., located higher than or lower than the topmost surface of the top electrode 18. In some embodiments, the second horizontal portion 12C and the vertical portion 12B of the bottom electrode 12 can be omitted.

The bottom electrode 12 can be composed of a first electrode material such as, for example, Ta, TaN, Ti, TiN, Ru, RuN, RuTa, RuTaN, W, WN or any combination or multilayered stack thereof. When the bottom electrode 12 includes the first horizontal portion 12A, the second horizontal portion 12C, and the vertical portion 12B each of these portions can be composed of a compositionally same, or compositionally different, first electrode material. The top electrode 18 can be composed of a second electrode material such as, for example, Ta, TaN, Ti, TiN, Ru, RuN, RuTa, RuTaN, W, WN or any combination or multilayered stack thereof. In some embodiments of the present application, the second electrode material that provides the top electrode 18 can be compositionally the same as the first electrode material that provides the bottom electrode 12. For example, both the bottom electrode 12 and the top electrode 18 can be composed of Ti. In other embodiments of the present application, the second electrode material that provides the top electrode 18 can be compositionally different from the first electrode material that provides the bottom electrode 12. For example, the bottom electrode 12 can be composed of Ti, and the top electrode 18 can be composed of TiN.

The CMO structure 14 is a structure that has a defect-assisted conduction and high non-linearity between defect concentration and electrical resistivities. The CMO structure 14 has a lower conductivity, σ, and thermal conductivity, k, as compared to the cylindrical metallic filament 16. That is, σ_{CMO} is less than σ_{MF}, and k_{CMO} is less than k_{MF}. As such, the CMO structure 14 can act as an electric field and a thermal confinement layer, due to spreading and thermal resistances. A further explanation of this can be found, for example, in an article to Falcone et al. entitled “Analytic Modelling of the Transport in Analog Filamentary Conductive-Metal-Oxide/HfOₓ ReRAM Devices”, Nanoscale Horizons, Issue 5, 2024. A gradual migration of defects (i.e., oxygen vacancy defects 15) within the CMO structure 14 is triggered once a required migration energy is provided by both the electric field and temperature confinement causing a resistive switching. In some embodiments, and for NVM applications, the defect migration is equal to, or greater than, 1 eV, with a defect migration of from 1 eV to 1.5 eV being more typical. The CMO structure 14 is composed of a metal oxide including, but not limited to, TaOₓ, CeOₓ, TiOₓ, WOₓ, GaO_{X} or any combination or multilayered stack thereof. In the exemplary metal oxides listed herein, x is an integer or a portion of a number (e.g., 2 or 3.3). The CMO structure 14 includes oxygen vacancy defects 15 present therein. Throughout the present application, the term “oxygen vacancy defects” represents a loss of oxygen atoms from their respective position in a crystal lattice and mainly exist in the bulk and or the surface and subsurface of the CMO structure 14. The CMO structure 14 has an oxygen vacancy defect concentration, N_{Vo}, that is randomly distributed throughout the CMO structure 14 in a low-resistive state, and as the resistive state increases, the N_{Vo}, being to pile up at the topmost surface of the CMO structure 14 in a location beneath the cylindrical metallic filament 16 (this aspect of the present application will be exemplified in greater detail herein below). In some embodiments of the present application, the CMO structure 14 has a thickness, T_{CMO}, (as measured from a bottommost surface to a topmost surface of the CMO structure 14) of from 2 nm to 100 nm, with T_{CMO} from 10 nm to 30 nm being more typical.

As mentioned above, the cylindrical metallic filament 16 substantially confines the electric potential of the top electrode 18 in the circular plug area of π(r_{MF})². The cylindrical metallic filament 16 is composed of a metal dielectric material including, but not limited to, TiN, TaN or any combination or multilayered stack thereof. The cylindrical metallic filament 16 is typically tapered such that the radius of the cylindrical metallic filament 16 decreases from a topmost surface of the cylindrical metallic filament 16 to a bottommost surface of the cylindrical metallic filament 16. In some embodiments of the present application, cylindrical metallic filament 16 has a thickness, T_{MF}, (as measured from a bottommost surface to a topmost surface of the cylindrical metallic filament 16) of from 2 nm to 50 nm, with T_{MF} from 20 nm to 50 nm being more typical.

As illustrated in FIGS. 1A-1B, the NVM cell, notably, the bottom electrode 12 of the NVM cell. is located on a substrate 10 and the entirety of the NVM cell is embedded in a dielectric region 20. The substrate 10 can include a front-end-of-the-line (FEOL) level including one or more semiconductor devices, such as, for example, field effect transistors located on a semiconductor material; a middle-of-the-line (MOL) level including a plurality of metal contact structures embedded in a MOL dielectric material layer; at least one lower interconnect level of a BEOL structure that includes a plurality of lower interconnect structures embedded in a lower interconnect dielectric material layer; or any combination thereof. In one example, the substrate includes a FEOL level and a MOL level.

The dielectric region 20 is composed of at least one dielectric material and can be a component of a BEOL structure. Although not illustrated in FIGS. 1A-1B, one or more metal wiring regions can also be embedded in the dielectric region 20 in addition to the NVM cell of the present application. The dielectric material that provides the dielectric region 20 can include, but is not limited to, silicon dioxide, silicon nitride, hafnium oxide, aluminum oxide, undoped silicate glass (USG), fluorosilicate glass (FSG), borophosphosilicate glass (BPSG), a spin-on low-k dielectric material, a chemical vapor deposition (CVD) low-k dielectric material or any combination or multilayered stack thereof. The term “low-k” as used throughout the present application denotes a dielectric material that has a dielectric constant of less than 4.0. All dielectric constants mentioned herein are measured in a vacuum unless otherwise noted.

The NVM cells of the present application including those illustrated in FIG. 1A and 1B can be formed utilizing various techniques well known to those skilled in the art. For example, a damascene process which includes depositing a dielectric material, patterning the dielectric material include an opening, and then filling the opening with an appropriate material that provides one of the components/elements of the NVM cell of the present application can be used. These steps can be repeated to form the NVM cell of the present application. The filling of the opening can include a deposition process, followed by a planarization process such as, for example, chemical mechanical planarization (CMP). The deposition process can include, but is not limited to, chemical vapor deposition (CVD), plasma enhanced chemical vapor deposition (PECVD), atomic layer deposition (ALD), sputtering or plating. In another example, a substrative etching process can be employed in which one of the components/elements of the NVM cell of the present application is formed by deposition and lithographic patterning, and thereafter a dielectric material is formed by deposition, followed by a planarization process. These steps can be repeated to provide the other components/elements of the NVM cell of the present application.

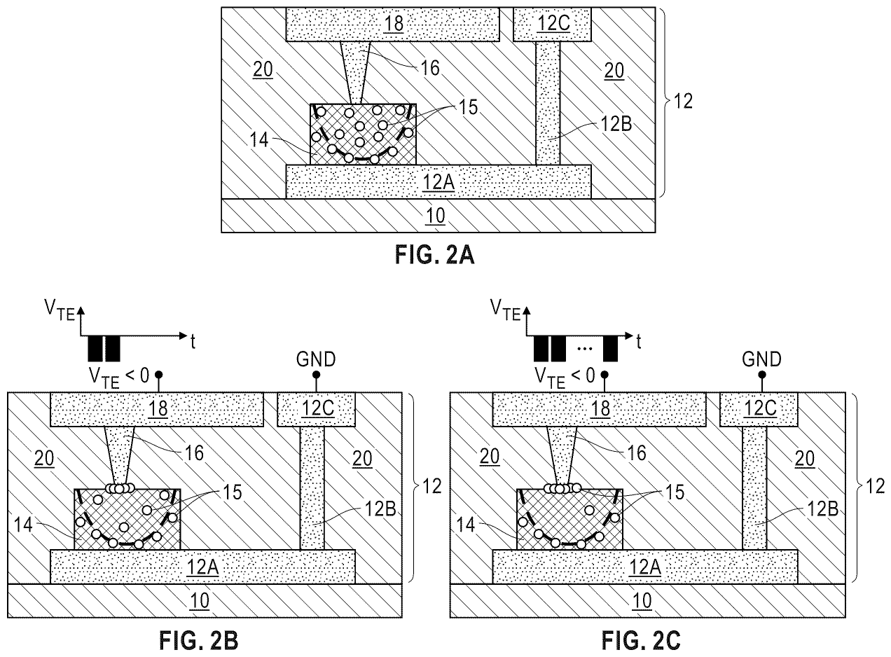

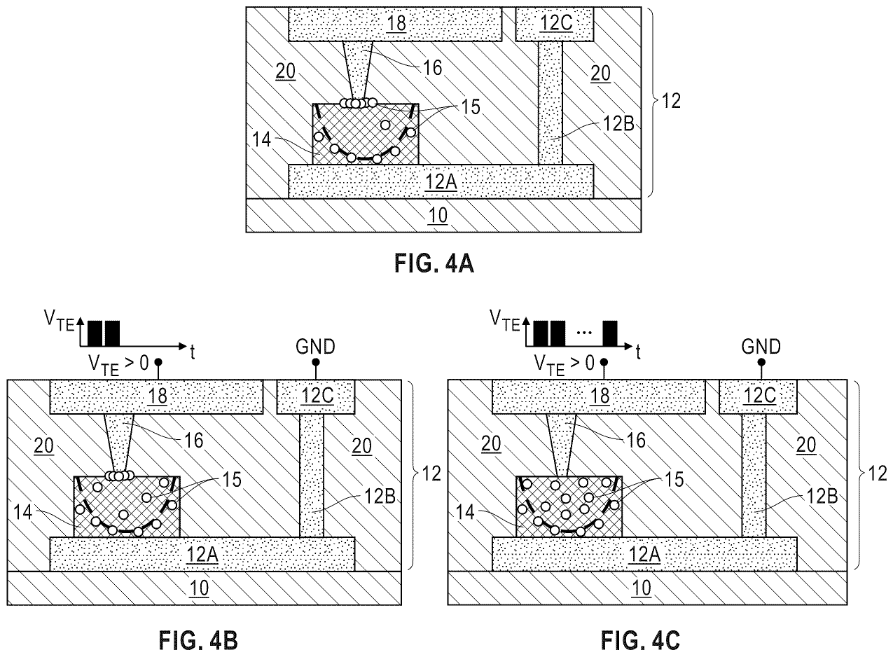

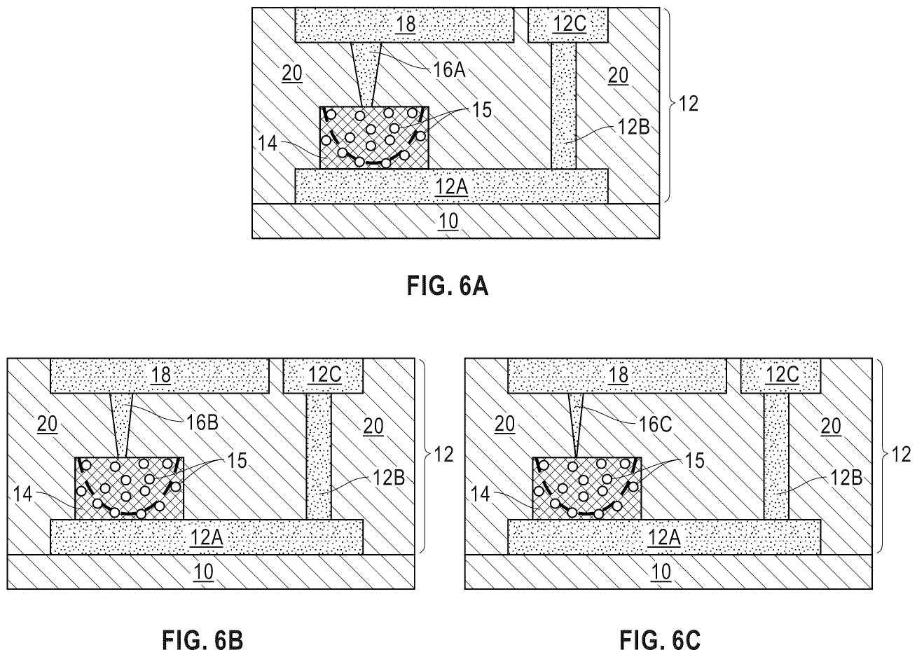

The NVM cell of the present application as exemplified in FIGS. 1A and 1B can undergo resistive switching through defect modulation in the CMO structure 14 (as illustrated, for example, in FIGS. 2A-2C and FIGS. 4A-4C). The resistive switching is bidirectional and can be a gradual resistive switching process (as illustrated, for example, in FIGS. 2A-2C and FIGS. 4A-4C). The resistive levels achieved in the present application are controlled levels (as illustrated, for example, in FIGS. 6A-6C).

Referring now to FIGS. 2A-2C, there are illustrated multi-level programming of an NVM cell in accordance with an embodiment of the present application. In the illustrated embodiment of FIGS. 2A-2C, a gradual increase of the cell resistance, R_{cell}, is observed. Notably, FIG. 2A illustrates a low resistive state, lrs, for an as-formed NVM cell such as illustrated in FIG. 1A above. As is illustrated in FIG. 2A and for the low resistive state, Rₗᵣₛ, the N_{Vo} is randomly distributed throughout the CMO structure 14. By applying identical negative voltage pulses to the top electrode 18, V_{TE}<0, with the bottom electrode 12 being grounded, a gradual decrease of N_{Vo} within the bulk of the cell is induced as is illustrated in FIGS. 2B and 2C, resulting in multi-level programming of the NVM cell. Notably, FIG. 2B illustrates an intermediate resistive state in which the N_{Vo} begins to increase at the topmost surface of the CMO structure 14 in a location beneath the cylindrical metallic filament 16, while FIG. 2C illustrates a high resistive state, Rₕᵣₛ, in which a greater N_{Vo} is found at the topmost surface of the CMO structure 14 as compared to the intermediate resistive state shown in FIG. 2B.

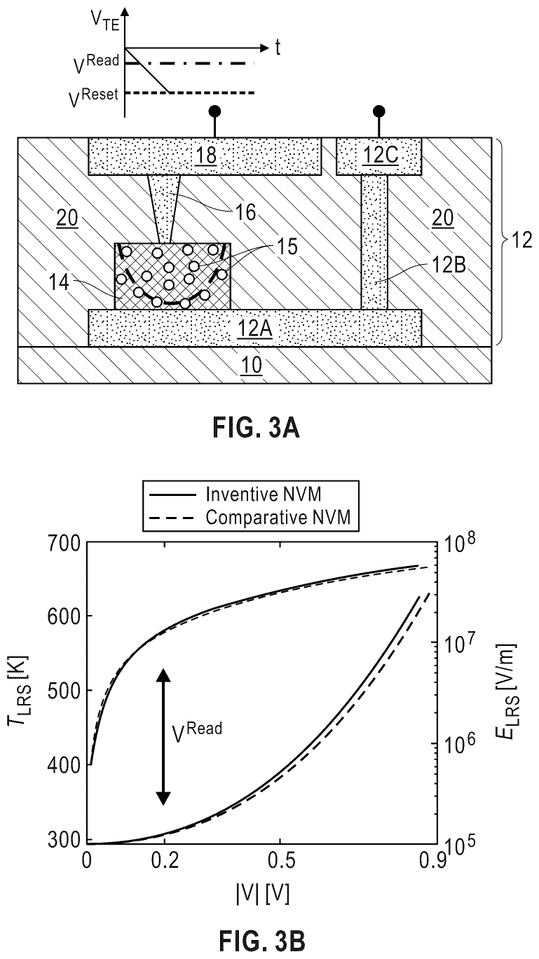

Referring now to FIG. 3A, there is illustrated the negative write and read operations for an exemplary NVM cell in accordance with an embodiment of the present application. Notably, FIG. 3A illustrates a NVM cell as shown in FIG. 1A using a CMO structure 14 that is composed of TaOₓ in which voltage can be applied to the top electrode 18 (with the bottom electrode 12 being grounded). In FIG. 3A, V_{TE} equals the volage that is applied to the top electrode 18, V^{Read} denotes the voltage from non-destructive read-out of the resistive state, V^{Reset} denotes the voltage to start the reset process, and t is the time. To enable the gradual migration of oxygen vacancy defects 15 migration within the CMO structure 14 and for this specific embodiment, the active energy, E_{A} was 1.4 eV, the temperature, T, was 630 Kelvin (K) and the electric field, E, was 6.67E⁷ V/m.

In this specific example, the cylindrical metallic filament 16 has a radius near the CMO structure 14 that is 25 nm, σ_{Taox} is 2E³ siemens/meters (S/m), σ_{MF} is 5E5 S/M, the low resistance state, R_{lrs.} is 3 kilo ohms, k_{Taox} is 1 W/mK and k_{MF} is 23 W/mk. In this specific example, a comparison is made to a conventional conductive filament (CF) ReRAM (e.g., TaOₓ/HfOₓ) in which the radius of the CF is r_{CF} is 25 nm, σ_{TaOx} is 2E³ S/m, σ_{CF} is 4.2E4 S/M, Rₗᵣₛ is 3 kohms, k_{Taox} is 1 W/mK and k_{CF} is 23 W/mk. Note that the conventional CF ReRAM and the NVM cell of the present application have a same electrical resistance in the low resistive state.

As is shown in FIG. 3B, the cylindrical metallic filament 16 within the NVM cell illustrated in FIG. 3A allowed a comparable electric field (E) and temperature (T) confinement in the TaOx based CMO structure 14 with respect to a conventional CF resulting in similar electrical performances (i.e., V^{Reset} amplitudes, reset switching dynamics and non-destructive reading).

Referring now to FIG. 4A-4C, there are illustrated multi-level programming of an NVM cell in accordance with an embodiment of the present application. In the illustrated embodiment of FIGS. 4A-4C, a gradual decrease of the cell resistance, R_{cell}, is observed. Notably, FIG. 4A illustrates a high resistive state, Rₕᵣₛ, for a NVM cell such as illustrated in FIG. 3A. As is illustrated in FIG. 4A and for the high resistive state, Rₕᵣₛ, a high N_{Vo} is found at the topmost surface of the CMO structure 14 as compared to the intermediate resistive state shown in FIG. 4B. By applying identical positive voltage pulses to the top electrode 18, V_{TE}>0, with the bottom electrode 12 being grounded, a gradual increase of N_{Vo} in the bulk of the CMO structure 14 is observed as is shown in FIGS. 4B and 4C. Notably, FIG. 4B illustrates an intermediate resistive state in which the N_{Vo} begins to decrease the topmost surface of the CMO structure 14 in a located than is located beneath the cylindrical metallic filament 16, while FIG. 4C illustrates a low resistive state, Rₗᵣₛ, in which a greater N_{Vo} is found in the bulk of the CMO structure 14 as compared to the intermediate resistive state shown in FIG. 4B or the high resistive state, Rₕᵣₛ, as shown in FIG. 4A.

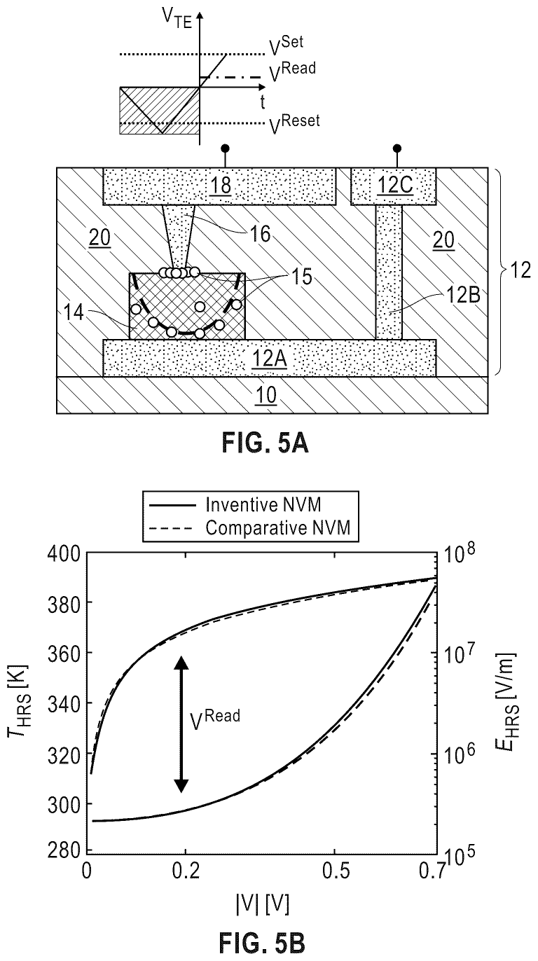

Referring now to FIG. 5A, there is illustrated the positive write and read operations for an exemplary NVM cell in accordance with an embodiment of the present application. Notably, FIG. 5A illustrates a NVM cell as shown in FIG. 1A using a CMO structure 14 that is composed of TaOₓ in which voltage can be applied to the top electrode 18 (with the bottom electrode 12 being grounded). In FIG. 5A, V_{TE} equals the volage that is applied to the top electrode 18, V^{Read} denotes the voltage from non-destructive read-out of the resistive state, V^{Reset} denotes the voltage to start the reset process, and t is the time. To enable the gradual migration of oxygen vacancy defects 15 migration within the CMO structure 14 and for this specific embodiment, the active energy, E_{A} was 1.3 eV, T was 380 Kelvin (K) and E was 5.5E⁷ V/m.

In this specific example, the cylindrical metallic filament 16 has a radius near the CMO structure 14 that is 25 nm, σ_{TaOx} is 2E³ S/m, σ_{MF} is 5E5 S/M, high resistance state, Rₕᵣₛ is 8 kilo ohms, k_{Taox} is 1 W/mK and k_{MF} is 23 W/mk. In this specific example, a comparison is made to a conventional CF ReRAM (e.g., TaOₓ/HfOₓ) in which the radius of the CF is r_{CF} is 25 nm, σ_{TaOx} is 2E³ S/m, σ_{CF} is 4.2E4 S/M, Rₗᵣₛ is 3 kohms, k_{Taox} is 1 W/mK and k_{CF} is 23 W/mk. Note that the conventional CF ReRAM and the NVM cell of the present application have a same electrical resistance in the high resistive state.

As is shown in FIG. 5B, the cylindrical metallic filament 16 within the NVM cell illustrated in FIG. 3A allowed a comparable electric field (E) and temperature (T) confinement in the TaOₓ based CMO structure 14 with respect to conventional CF resulting in similar electrical performances (i.e., V^{Reset} amplitudes, reset switching dynamics and non-destructive reading).

Referring now to FIGS. 6A-6C, there are illustrated various exemplary 2-terminals forming-free CMO-based MF-ReRAM cells in accordance with an embodiment of the present application showing controllable resistive switching levels, Rₗᵣₛ and Rₕᵣₛ, that can be achieved by varying the radius of the cylindrical metallic filament 16, r_{MF}. In this illustrated embodiment, each NVM cell included a CMO structure 14 that is composed of TaOₓ in which the cylindrical metallic filament 16 of each of the NVM cells had a different radius near the CMO structure 14. Notably, the radius of the cylindrical metallic filament 16, r_{MF}, near the CMO structure 14 for the NVM cell illustrated in FIG. 6A was 25 nm, the radius of the cylindrical metallic filament 16, r_{MF}, near the CMO structure 14 for the NVM cell illustrated in FIG. 6B was 15 nm, and the radius of the cylindrical metallic filament 16, r_{MF}, near the CMO structure 14 for the NVM cell illustrated in FIG. 6C was 5 nm. In one embodiment, σ_{TaOx} is 2E³ S/m for each of the NVM cells illustrated in FIGS. 6A-6C. For this embodiment, the resistance is approximately equal to (2πσ_{TaOx} r_{Mf})⁻¹. In the embodiment, the following resistive switching levels, Rₗᵣₛ and Rₕᵣₛ, were achieved: (I) for the NVM cell illustrated in FIG. 6A in which r_{MF} is equal to 25 nm, Rₗᵣₛ is approximately equal to 3 kilo ohms and Rₕᵣₛ is approximately equal to 9 kilo ohms; (II) for the NVM cell illustrated in FIG. 6B in which r_{MF} is equal to 15 nm, Rₗᵣₛ is approximately equal to 5 kilo ohms and Rₕᵣₛ is approximately equal to 15 kilo ohms; and (III) for the NVM cell illustrated in FIG. 6C in which r_{MF} is equal to 15 nm, Rₗᵣₛ is approximately equal to 15 kilo ohms and Rₕᵣₛ is approximately equal to 45 kilo ohms. Notably and for this embodiment, as r_{MF} decreases, both the Rₗᵣₛ and the Rₕᵣₛ increase.

In another embodiment, and using the NVM cells illustrated in FIGS. 6A-6C, controllable resistive switching levels, Rₗᵣₛ and Rₕᵣₛ, can be achieved by varying both the radius of the cylindrical metallic filament 16, r_{MF}, near the CMO structure 14 and the concentration of oxygen vacancy defects 15. In this embodiment, σ_{TaOx} is 1E² S/m for each of the NVM cells illustrated in FIGS. 6A-6C. For this embodiment, the resistance is approximately equal to (2πσ_{TaOx} r_{MF})⁻¹. In the embodiment, the following resistive switching levels, Rₗᵣₛ and Rₕᵣₛ, were achieved: (I) for the NVM cell illustrated in FIG. 6A in which r_{MF} is equal to 25 nm, Rₗᵣₛ is approximately equal to 60 kilo ohms and Rₕᵣₛ is approximately equal to 180 kilo ohms; (II) for the NVM cell illustrated in FIG. 6B in which r_{MF} is equal to 15 nm, Rₗᵣₛ is approximately equal to 100 kilo ohms and Rₕᵣₛ is approximately equal to 300 kilo ohms; and (III) for the NVM cell illustrated in FIG. 6C in which r_{MF} is equal to 15 nm, Rₗᵣₛ is approximately equal to 300 kilo ohms and Rₕᵣₛ is approximately equal to 900 kilo ohms. Notably and for this embodiment, as r_{MF} decreases, both the Rₗᵣₛ and the Rₕᵣₛ increase. Also, and for this embodiment, an increase in the concentration of oxygen vacancy defects 15 in the CMO structure 14 provided a greater increase in both Rₗᵣₛ and the Rₕᵣₛ as compared to the previous embodiment in which σ_{TaOx} is 2E³ S/m.

Although not specifically illustrated, an increase in concentration of oxygen vacancy defects in the CMO structure 14 from one NVM cell to another NVM cell having an identical r_{MF} can provide controllable resistive switching levels, Rₗᵣₛ and Rₕᵣₛ.

Referring now to FIG. 7A, there is illustrated a 1T-1MFReRAM cell 40 in accordance with an embodiment of the present application. FIG. 7B show a circuit diagram of the 1T-1MFReRAM cell 40 illustrated in FIG. 7A. Notably, the 1T-1MFReRAM cell 40 illustrated in FIG. 7A includes an nMOS transistor located on surface of a semiconductor substrate 42 including a p-well 44. The nMOS transistor includes a pair of source/drain regions 46 (one of which serves as a source region of the transistor, and the other of which serves as a drain region of the transistor) embedded in the p-well 44 and located at a footprint of a gate structure 48 (gate structure 48 includes a gate dielectric material and a gate electrode). As is illustrated in FIG. 7A, one of the source/drain regions 46 (typically the source region) of the nMOS transistor is electrically connected to a first wiring region, W1, via a first source/drain contact structure 50A. The first wiring region, W1, includes a plurality of metal lines, e.g., M1, M2, and M3, in which each of the metal lines is interconnected to another metal line by a metal via, e.g., V1 and V2. Note that V1 of the first wiring region, W1, interconnects M1 with M2, and V2 of the first wiring region, W1, interconnects M2 with M3. As is further illustrated, the gate structure 48 is electrically connected to a second wiring region, W2, via a gate contact structure 50B. The second wiring region, W1, includes a plurality of metal lines, e.g., M1, M2, and M3, in which each of the metal lines is interconnected to another metal line by a metal via, e.g., V1 and V2. Note that V1 of the second wiring region, W2, interconnects M1 with M2, and V2 of the first wiring region, W1, interconnects M2 with M3. It is noted that while an nMOS transistor is described and illustrated, the present application works when the nMOS transistor is replaced with a pMOS transistor. In such embodiments, the p-well 44 would be replaced with an n-well. In the exemplary embodiment of FIG. 7A, the first wiring region, W1, can be serves as a portion of a source line (SL), the second wiring region, W2, can serves as a portion of a word line (WL), and the third wiring region, W3, can serves as part of a bit line (BL).

The 1T-1MFReRAM cell 40 also includes a NVM cell in accordance with the present

application that includes bottom electrode 12, CMO structure 14, cylindrical metallic filament 16 and top electrode 18, as defined above. The NVM cell is located at a same level as the M1 and M2 levels of first and second wiring regions. As is illustrated, the bottom electrode 12 of the NVM cell is electrically connected to another of the source/drain regions 46 (typically the drain region) of the n-MOS transistor via a second source/drain contact structure 50C. As is further illustrated in FIG. 7A, the top electrode 18 of the NVM cell is electrically connected to M3 of a third wiring region, W3, via V2.

As is illustrated, a dielectric structure 52 including various dielectric layer, namely first

dielectric layer 52A, second dielectric layer 52B, three dielectric layer 52C and fourth dielectric layer 52D embeds the nMOS transistor and the NVM cell. The dielectric structure 52 is equivalent to dielectric region 20 mentioned above, and the various dielectric layers of dielectric structure 52 include one of the dielectric materials mentioned above for the dielectric region 20. The dielectric structure 52 includes a MOL level and a BEOL level. The MOL level includes the first dielectric layer 42A in which the first source/drain contact structure 50A, the gate contact structure 50B and the second source/drain contact structure 50C are embedded therein. The BEOL level includes the NVM cell and the various wiring regions embedded in the second-fourth dielectric layers.

Referring now to FIG. 7C, there is illustrated a circuit diagram including a plurality of

1T-1MFReRAM cells 40 in a high density crossbar memory architecture. Notably, FIG. 7C illustrates that the disclosed NVM cell of the present application can be integrated in a BEOL of advanced CMOS technology nodes. Specifically, FIG. 7C illustrates that a plurality of 1T-1MFReRAM cells 40 as shown in FIGS. 7A-7B can be densely integrated in a cross bar architecture that includes bit lines, BL, word lines, WL, and source lines (SL). The plurality of 1T-1MFReRAM cells 40 can be arranged in rows and columns as shown in FIG. 7C. The illustrated embodiment includes three bit lines, namely first bit line BL1, second bit line BL2, and third bit line BL3, three word lines, WL, namely first word line WL1, second word line WL2 and third word line WL3, and three source lines, SL, namely first source line SL1, second source line SL2 and third source line SL3. It noted that the number of bit lines, source lines and word lines is not limited to that number illustrated in FIG. 7C. In the illustrated embodiment, the bit lines, e.g., BL1, BL2 and BL3, are horizontal lines, each connecting all the top electrodes 18 of the NVM cell in the corresponding row, the source lines, e.g., SL1, SL2 and SL3, are vertical lines, each connecting all the source regions of the nMOS transistors in the corresponding column, and the word lines, e.g., WL1, WL2, and WL3, are horizontal lines connecting all the gate electrodes present in each gate structure 48 of the nMOS transistors in the corresponding row. Such architecture ensures single-cell write/read operations without perturbing all other cells.

In another embodiment, the NVM cell of the present application can used in a MF-ReRAM

cross bar array as illustrated in FIG. 8 and exploited to performance parallel AI workloads (training and inference). Such an array can be used as a high parallel high-density AIMC accelerator. In FIG. 8, each NVM cell is a MF-ReRAM cell 50 in accordance with the present application that includes bottom electrode 12, CMO structure 14, cylindrical metallic filament 16 and top electrode 18, as defined above. Specifically, FIG. 8 illustrates that a plurality of MF-ReRAM cells 50 can be densely integrated in a cross bar architecture that includes bit lines, BL, and source lines (SL). The plurality of MF-ReRAM cells 50 can be arranged in rows and columns as shown in FIG. 8. The illustrated embodiment includes three bit lines, namely first bit line BL1, second bit line BL2, and third bit line BL3, and three source lines, SL, namely first source line SL1, second source line SL2 and third source line SL3. It noted that the number of source lines and word lines is not limited to that number illustrated in FIG. 8. In the illustrated embodiment, the bit lines, e.g., BL1, BL2 and BL3, are horizontal lines, each connecting all the top electrodes 18 of the MF-ReRAM cell in the corresponding row, the source lines, e.g., SL1, SL2 and SL3, are vertical lines, each connect to the bottom electrode 12 of the MF-ReRAM cells 50 in the corresponding column. Specifically, the MF-ReRAM cells 50 illustrated in FIG. 8 can be used as neural network for parallel read-out and weight updates using backpropagation with pulse coincidence. The weight updates implementation time reduced from digital O(n²) to O(1)a.

While the present application has been particularly shown and described with respect

to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A non-volatile memory (NVM) cell comprising:
a conductive metal oxide (CMO) structure located on a portion of a bottom electrode; and
a top electrode located above the CMO structure, wherein the top electrode is connected to the CMO structure by a cylindrical metallic filament, wherein the cylindrical metallic filament substantially confines electric potential of the top electrode in a circular plug area of π(r_{MF})², wherein r_{MF} is a radius of the cylindrical metallic filament, as measured from a bottommost portion of the cylindrical metallic filament.

2. The NVM cell of claim 1, wherein the cylindrical metallic filament is in direct physical contact with the CMO structure.

3. The NVM cell of claim 1, further comprising a diffusion barrier layer separating the cylindrical metallic filament from the CMO structure.

4. The NVM cell of claim 1, further comprising a dielectric region embedding each of the bottom electrode, the CMO structure, the cylindrical metallic filament and the top electrode.

5. The NVM cell of claim 4, wherein the dielectric region is a component of an back-end-of-the-line (BEOL) structure.

6. The NVM cell of claim 1, wherein the CMO structure has a lower conductivity, σ, and thermal conductivity, k, as compared to the cylindrical metallic filament.

7. The NVM cell of claim 1, wherein the CMO structure is composed of a metal having a concentration of oxygen vacancy defects present therein, wherein a modulation of the oxygen vacancy defects in the CMO structure provides analog resistive switching.

8. The NVM cell of claim 7, wherein the concentration of the oxygen vacancy defects is randomly distributed throughout the CMO structure and the NVM cell is at a low-resistive state.

9. The NVM cell of claim 7, wherein the concentration of the oxygen vacancy defects is greater at a topmost surface of the CMO structure than a bulk portion of the CMO structure and the NVM cell is a high resistive state.

10. The NVM cell of claim 7, wherein a resistive state of the CMO structure is controlled by the r_{MF}, a concentration of the oxygen vacancy defects in the CMO structure or a combination of r_{MF} and the concentration of the oxygen vacancy defects present in the CMO structure.

11. A crossbar memory architecture comprising:
a plurality 1T-1MFReRAM cells arranged in rows and columns, each 1T-1MFReRAM cell comprising a transistor and a NVM cell, the NVM cell comprises a conductive metal oxide (CMO) structure located on a portion of a bottom electrode, and a top electrode located above the CMO structure, wherein the top electrode is connected to the CMO structure by a cylindrical metallic filament, wherein the cylindrical metallic filament substantially confines electric potential of the top electrode in a circular plug area of π(r_{MF})², wherein r_{MF} is a radius of the cylindrical metallic filament, as measured from a bottommost portion of the cylindrical metallic filament;
at least one horizontal line of bit lines, each bit line in the at least one horizontal line of bit lines is connected to the top electrode of each NVM cell in a corresponding row of 1T-1MFReRAM cells;
at least one horizontal line of word lines, each word line in the at least one horizontal line of word lines is connected to a gate electrode of each of the transistors in a corresponding row of 1T-1MFReRAM cells; and
at least one vertical line of source lines, each source line is connected to a source region of each of the transistors in a corresponding column of 1T-1MFReRAM cells.

12. The crossbar memory architecture of claim 11, wherein the cylindrical metallic filament of each NVM cell is in direct physical contact with the CMO structure.

13. The crossbar memory architecture of claim 11, further comprising a diffusion barrier layer separating the cylindrical metallic filament from the CMO structure of each NVM cell.

14. The crossbar memory architecture claim 11, wherein the CMO structure has a lower conductivity, σ, and thermal conductivity, k, as compared to the cylindrical metallic filament.

15. The crossbar memory architecture of claim 11, wherein the CMO structure is composed of a metal having a concentration of oxygen vacancy defects present therein, wherein a modulation of the oxygen vacancy defects in the CMO structure provides analog resistive switching.

16. The crossbar memory architecture of claim 15, wherein a resistive state of the CMO structure is controlled by the r_{MF}, a concentration of the oxygen vacancy defects in the CMO structure or a combination of r_{MF} and the concentration of the oxygen vacancy defects present in the CMO structure.

17. A crossbar memory architecture comprising:
a plurality MF-ReRAM cells arranged in rows and columns, each MF-ReRAM includes a CMO structure located on a portion of a bottom electrode, and a top electrode located above the CMO structure, in which the top electrode is connected to the CMO structure by a cylindrical metallic filament, and the cylindrical metallic filament substantially confines electric potential of the top electrode in a circular plug area of π(r_{MF})², where r_{MF} is a radius of the cylindrical metallic filament, as measured from a bottommost portion of the cylindrical metallic filament;
at least one horizontal line of bit lines, each bit line in the at least one horizontal line of bit lines is connected to the top electrode of each 1MFReRAM cell; and at least one vertical line of source lines, each source line is connected to the bottom electrode of each 1MFReRAM cell.

18. The crossbar memory architecture claim 17, wherein the CMO structure has a lower conductivity, σ, and thermal conductivity, k, as compared to the cylindrical metallic filament.

19. The crossbar memory architecture of claim 17, wherein the CMO structure is composed of a metal having a concentration of oxygen vacancy defects present therein, wherein a modulation of the oxygen vacancy defects in the CMO structure provides analog resistive switching.

20. The crossbar memory architecture of claim 19, wherein a resistive state of the CMO structure is controlled by the r_{MF}, a concentration of the oxygen vacancy defects in the CMO structure or a combination of r_{MF} and the concentration of the oxygen vacancy defects present in the CMO structure.
